(19) United States
(12) Patent Application Publication
(10) Pub. No.: US 2025/0176150 A1
(43) Pub. Date: May 29, 2025

(54) ELECTRONIC MODULE COMPRISING AN ELECTRONIC CARD, A HOUSING AND A PROTECTIVE PARTITION

(71) Applicant: Valeo eAutomotive Germany GmbH, Erlangen (DE)

(72) Inventors: Patrick LEBRASSEUR, Cergy Pontoise (FR); Roger DENIOT, Cergy Pontoise (FR)

(73) Assignee: Valeo eAutomotive Germany GmbH, Erlangen (DE)

(21) Appl. No.: 18/956,690

(22) Filed: Nov. 22, 2024

(30) Foreign Application Priority Data
Nov. 23, 2023 (FR) 2312941

(51) Int. Cl. H05K 9/00; H05K 5/00; H05K 5/06

(52) U.S. Cl. CPC H05K 9/0037; H05K 5/0052; H05K 5/006; H05K 5/069

(57) ABSTRACT

An electronic module includes an electronic card, a housing in which the electronic card is placed, a protective partition which is secured on the housing and the electronic card such that the electronic card is engaged between the housing and the protective partition, and at least one securing element designed to render the electronic card, the housing and the protective partition integral. The housing and the protective partition are made of electrically conductive materials and secured together with the protective partition by the at least one securing element. At least one securing element includes an area of electrical contact, and assures an electrical contact between the housing, the protective partition and an electrical ground of the electronic card.

The present invention concerns an electronic module comprising an electronic card, a housing and a protective partition.

This electronic module can be incorporated in a vehicle with hybrid or purely electric propulsion, for example a motor vehicle. More generally, the term “vehicle” encompasses, within the meaning of the present patent application, any form of mobility, irrespective of whether it is propelled by purely electric, hybrid, internal-combustion or other means. Thus, the term “vehicle” encompasses a machine travelling on the ground with four, three, two or any other number of wheels, or a machine moving through the air or on water, or even through space.

It is known to place an electronic card in an insulating housing making it possible to protect the surrounding parts against the magnetic fields emitted by this electronic card during its operation.

The objective of the invention is to improve the implementation of this function of electromagnetic protection by decreasing the space dedicated to this function on the electronic card, and by reducing the costs necessary for this electromagnetic protection.

The invention concerns an electronic module comprising:
An electronic card;
A housing in which the electronic card is placed;
A protective partition which is secured on the housing and the electronic card, such that the electronic card is engaged between the housing and the protective partition;
At least one securing element designed to render the electronic card, the housing and the protective partition integral,
   characterised in that:
the housing and the protective partition are made of electrically conductive materials;
the housing, the electronic card and the protective partition are secured together by the at least one securing element;
at least one securing element comprises an electrical contact area, and also assures an electrical contact between the housing, the protective partition and an electrical ground of the electronic card.

According to an aspect of the invention, the housing and the protective partition form an electromagnetic protective enclosure, which is designed to insulate the electronic card, and protect the electronic card against the exterior, in particular against electromagnetic disturbances.

According to an aspect of the invention, the electromagnetic protective enclosure is also designed to protect the exterior environment against the electromagnetic fields produced by the electronic card.

According to an aspect of the invention, the electronic card comprises a flat substrate, on which electronic components are welded.

According to an aspect of the invention, electronic components are welded on each face of the flat substrate.

Alternatively, all of the electronic components are welded on one face of the flat substrate.

According to an aspect of the invention, a face of the electronic card is placed in contact with the housing. This face will be known as the lower face of the electronic card.

According to an aspect of the invention, a face of the electronic card is in electrical contact with the protective partition. This face will be known as the upper face of the electronic card.

According to an aspect of the invention, the housing is made of aluminium.

According to an aspect of the invention, the protective partition is made of aluminium.

According to an aspect of the invention, the housing comprises a base, in particular a substantially flat base.

According to an aspect of the invention, the housing comprises a peripheral border, substantially perpendicular to the base of the housing, and surrounding the base of the housing.

According to an aspect of the invention, the peripheral border and the base of the housing form a vessel in which the electronic card is placed.

According to an aspect of the invention, the housing comprises at least one area of contact, which is designed to be placed in contact with the electronic card during the assembly of the electronic module.

According to an aspect of the invention, the housing contains a plurality of areas of contact, which are known as areas of contact of the housing.

According to an aspect of the invention, at least one of the areas of contact of the housing is a support border.

A support border is an area of contact of the housing juxtaposed with the peripheral border of the housing.

According to an aspect of the invention, the housing comprises at least one contact stud.

According to an aspect of the invention, the contact studs are volumes of the housings placed on the base of the housing.

According to an aspect of the invention, each contact stud comprises a flat upper surface.

According to an aspect of the invention, the contact studs have a round form.

Alternatively, the contact studs can have any other form, in particular a rectangular or oval form.

According to an aspect of the invention, the upper surfaces of the contact studs of the housing are areas of contact of the housing.

According to an aspect of the invention, at least one area of contact of the housing is an electrical area of contact of the housing, and is designed to guarantee an electrical contact between the housing and an electrical ground of the electronic card.

According to an aspect of the invention, all of the areas of contact of the housing are flat and coplanar, and define a contact plane of the housing.

According to an aspect of the invention, the contact plane of the housing is parallel to the base of the housing.

According to an aspect of the invention, the contact plane of the housing is raised in relation to the base of the housing.

For example, the contact plane is raised from the base of the housing by a height H1 greater than 20 mm.

According to an aspect of the invention, the height H1 is greater than the maximal thickness of the electronic components which are welded on the lower face of the electronic card, such that the electronic components welded on the lower face of the electronic card are not in contact with the housing, once the electronic card is placed in electrical contact with the housing.

According to an aspect of the invention, the base of the housing, the peripheral border of the housing, the support border and the contact studs are produced in a single piece, for example by moulding, or by machining.

Consequently, all of the areas of electrical contact of the housing are connected electrically.

According to an aspect of the invention, the protective partition has a substantially planar form. A main plane of the protective partition is defined.

According to an aspect of the invention, the protective partition contains a plurality of areas of contact, known as areas of contact of the protective partition, which are designed to be placed in contact with the electronic card during the assembly of the electronic module.

According to an aspect of the invention, at least one of the areas of contact of the protective partition is a border of contact of the protective partition.

A border of contact of the protective partition is an area of contact juxtaposed with the periphery of the protective partition.

According to an aspect of the invention, the protective partition comprises at least one central area of contact.

The central areas of contact are areas of contact of the protective partition which are not connected to the periphery of the protective partition.

According to an aspect of the invention, at least one area of contact of the protective partition is an electrical area of contact of the protective partition, and is designed to guarantee an electrical contact between the protective partition and an electrical ground of the electronic card.

According to an aspect of the invention, all of the areas of contact of the protective partition are flat and coplanar, and define a plane of contact of the protective partition.

According to an aspect of the invention, the plane of contact of the protective partition is parallel to the main plane of the protective partition.

According to an aspect of the invention, the plane of contact of the protective partition is offset relative to the main plane of the protective partition by a height H2 greater than 12 mm.

According to an aspect of the invention, the height H2 is greater than the maximum thickness of the electronic components which are welded on the upper face of the electronic card, such that the electronic components which are welded on the upper face of the electronic card are not in electrical contact with the protective partition, once the electronic card is placed in electrical contact with the protective partition.

According to an aspect of the invention, the electronic card comprises:
on the upper face, at least one upper area of contact of the electronic card;
on the lower face, at least one lower area of contact of the electronic card.

According to an aspect of the invention, at least one upper area of contact of the electronic card is an upper electrical area of contact of the electronic card.

According to an aspect of the invention, at least one lower area of contact of the electronic card is a lower electrical area of contact of the electronic card.

According to an aspect of the invention, the upper and lower areas of electrical contact of the card are connected electrically to the ground of the electronic card.

According to an aspect of the invention, the upper areas of contact of the electronic card are placed facing areas of contact of the protective partition, and are in contact with these areas of contact of the protective partition.

According to an aspect of the invention, the lower areas of contact of the electronic card are placed facing areas of contact of the housing, and are in contact with these areas of contact of the housing.

Thus, the electronic card is maintained secured between the housing and the protective partition.

According to an aspect of the invention, the lower areas of electrical contact of the electronic card are placed facing electrical areas of contact of the housing, and are in electrical contact with these electrical areas of contact of the housing.

According to aspect of the invention, the upper areas of electrical contact of the electronic card are placed facing electrical areas of contact of the protective partition, and are in electrical contact with these areas of electrical contact of the protective partition.

Thus, all of the housing and the protective partition is electrically connected to the electrical ground of the electronic card.

At least one area of contact of the housing is placed facing at least one area of contact of the protective partition.

At least one area of electrical contact of the housing is placed facing at least one area of electrical contact of the protective partition.

A combination of characteristics of the electronic module which makes it possible to render the housing, the electronic card and the protective partition integral is known as the securing element.

A securing element comprises:
a geometric characteristic of the electronic card;
a geometric characteristic of the protective partition;
a geometric characteristic of the housing;
and optionally at least one securing part.

A securing element comprises:
a portion of an upper area of electrical contact of the electronic card;
a portion of a lower area of electrical contact of the electronic card;
   these two areas of contact being placed facing one another;
a portion of an area of electrical contact of the housing placed facing the portion of a lower area of electrical contact of the electronic card;
a portion of an area of electrical contact of the protective partition placed facing the portion of an upper area of electrical contact of the electronic card.

For example, a securing element comprises:
a bore in the electronic card;
a bore in the protective partition;
a bore in the housing;
these bores being coaxial; and
a screw passing through all of the bores and securing the protective partition, the housing and the electronic card mechanically.

According to another embodiment, a securing area comprises:
a securing bore in the electronic card;
a bore respectively in the housing or the protective partition;
a securing stud formed respectively in the protective partition or the housing;
the securing stud being designed to be forced into the bores in order to secure the protective partition, the housing and the electronic card mechanically.

The electronic module comprises a cover forming a vessel, which is designed to be placed on the housing in order to close the housing.

The use of securing elements in order to provide the electrical contact between the electronic card, the protective partition and the housing advantageously makes it possible to reduce the space necessary allocated on the card for the function of electromagnetic protection. This therefore makes it possible to reduce the size of the electronic card, and to reduce the production costs.

Other characteristics, details and advantages of the invention will become more clearly apparent from reading the following description on the one hand, and from a plurality of embodiments provided by way of non-limiting indication with reference to the appended schematic drawings on the other hand, in which:

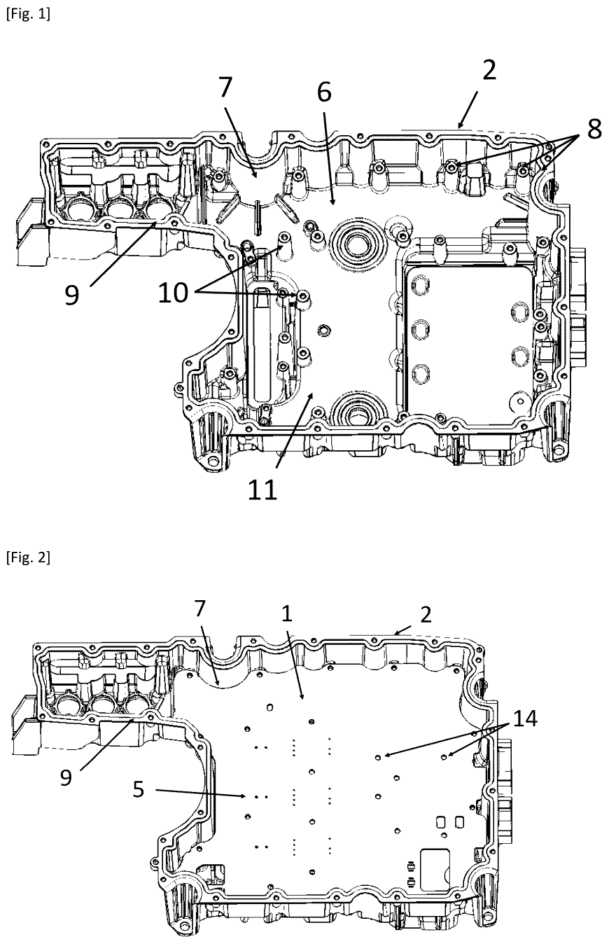

FIG. 1 is a schematic representation of a housing according to the invention.

FIG. 2 is a schematic representation of the assembly of a housing and an electronic card according to the invention.

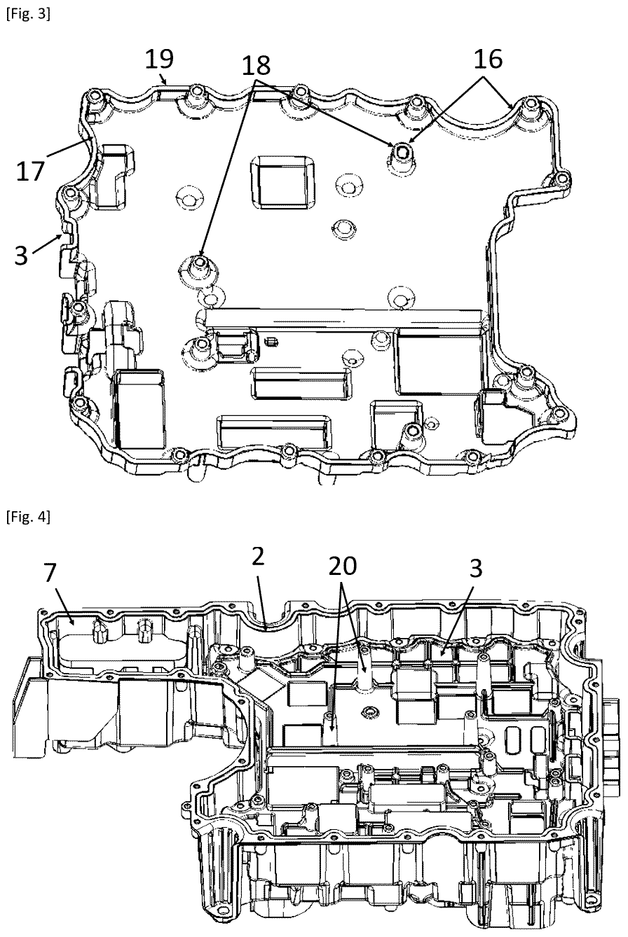

FIG. 3 is a schematic representation of a protective partition according to the invention.

FIG. 4 is a schematic representation of the assembly of a housing, an electronic card and a protective partition according to the invention.

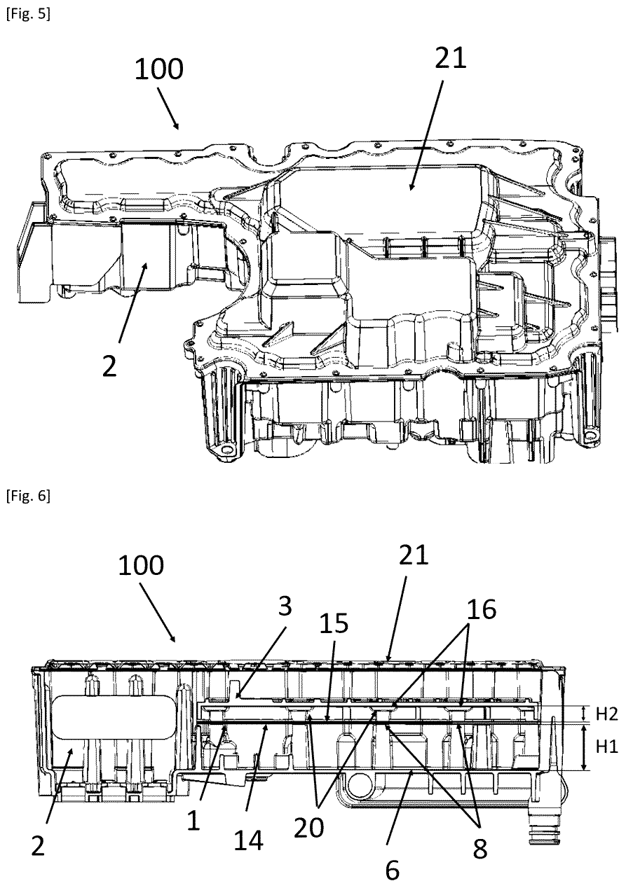

FIG. 5 is a schematic representation of the assembly of an electronic module according to the invention

FIG. 6 is a representation in cross-section of the assembly of an electronic module according to the invention.

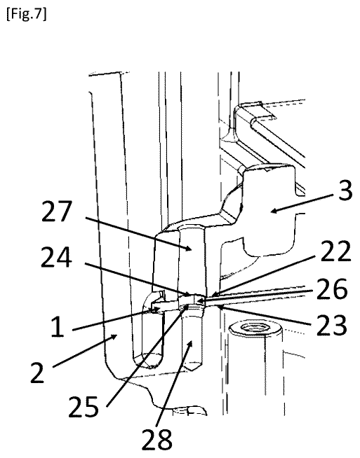

FIG. 7 is an enlarged view of an element for securing an electronic module according to the invention.

The characteristics, variants and different embodiments of the invention can be associated with one another according to various combinations, provided that they are not incompatible or mutually exclusive. In particular, it will be possible to conceive of variants of the invention which comprise only a selection of characteristics described hereinafter in isolation from the other characteristics described, if this selection of characteristics is sufficient to confer a technical advantage and/or to differentiate the invention from the prior art.

FIG. 1 represents a housing 2 of an electronic module 100 comprising a substantially flat base 6.

The housing comprises at least one area of contact of the housing 8, designed to be placed in contact with the electronic card 1 during the assembly of the electronic module 100.

The housing 2 comprises a peripheral border 7 which is substantially perpendicular to the base of the housing, and surrounds the base of the housing 6.

The peripheral border 7 and the base of the housing form a vessel 11, in which the electronic card is placed.

The housing 2 contains a plurality of areas of contact of the housing 8.

One of the areas of contact of the housing 8 is a support border 9, i.e. an area of contact of the housing 8 which is juxtaposed with the peripheral border 7 of the housing.

The housing comprises an upper face 12, in particular an upper face which is flat and parallel to the base of the housing 6.

The support border 9 has a substantially constant width, and extends along all of the peripheral border 7.

The housing 2 comprises at least one contact stud 10, i.e. a volume of the housing which is placed on the base of the housing 6. Each contact stud comprises a flat upper surface 13, these upper surfaces being areas of contact of the housing.

The contact studs 10 have a round form.

According to another embodiment, not represented, the contact studs 10 can have any other form, i.e. a rectangular or oval form.

At least one area of contact of the housing 8 is an electrical area of contact of the housing, and is designed to guarantee an electrical contact between the housing 2 and an electrical ground of the electronic card 1.

The base of the housing 6, the peripheral border of the housing 7, the support border 9 and the contact studs 10 are produced in a single piece, for example by moulding, or machining.

Consequently, all of the areas of electrical contact of the housing are connected electrically.

FIG. 2 represents the assembly of a housing 2 as illustrated in FIG. 1, and an electronic card 1 according to the invention.

The electronic card 1 is placed in the housing 2.

It comprises a flat substrate 5 on which there are welded electronic components, not represented here.

Electronic components are welded on each face of the flat substrate 5, or on only one of the faces of the flat substrate.

The electronic card 1 comprises:
on the upper face, at least one upper area of contact 14 of the electronic card;
on the lower face, at least one lower area of contact 15 of the electronic card, not shown in this figure.

The lower face of the electronic card is placed in contact with the housing 2.

At least one upper area of contact 14 of the electronic card 1 is an upper area of electrical contact of the electronic card, and at least one lower area of contact 15 of the electronic card is a lower area of electrical contact of the electronic card.

These upper and lower areas of electrical contact are connected electrically to the ground of the electronic card 1.

FIG. 3 represents a protective partition according to the invention.

The protective partition 3 has a substantially planar form. A main plane of the protective partition is thus defined.

The protective partition 3 contains a plurality of areas of contact, known as areas of contact of the protective partition 16. These areas of contact of the protective partition are flat and coplanar, and define a plane of contact of the protective partition.

One of the areas of contact of the protective partition 16 is a contact border of the protective partition 17, i.e. an area of contact which is juxtaposed with the periphery of the protective partition.

The protective partition 3 also has a plurality of central areas of contact 18.

The central areas of contact 18 are areas of contact of the protective partition 16 which are not connected to the periphery of the protective partition 19.

At least one area of contact of the protective partition 16 is an electrical area of contact of the protective partition, and is designed to guarantee an electrical contact between the protective partition 3 and an electrical ground of the electronic card 1.

FIG. 4 represents the assembly of a housing 2, an electronic card 1 and a protective partition 3.

The protective partition 3 is secured on the housing 2 and the electronic card 1, such that the electronic card is engaged between the housing and the protective partition.

The housing 2 and the protective partition 1 form a protective electromagnetic enclosure which is designed to insulate the electronic card, protect it against electromagnetic disturbances, and protect the exterior environment against the electromagnetic fields produced by the electronic card.

The housing 2 and the protective partition 3 are made of electrically conductive materials, for example of aluminium.

The lower areas of contact 14 of the electronic card are placed facing the areas of contact of the housing 8, and are in contact with these electrical areas of contact of the housing.

In addition, the upper areas of contact 15 of the electronic card are placed facing the areas of contact of the protective partition 16, and are in contact with these areas of contact of the protective partition.

Thus, the electronic card 1 is maintained secured between the housing 2 and the protective partition 3.

In addition, the lower areas of electrical contact of the electronic card 1 are placed facing the areas of electrical contact of the housing 2, in electrical contact with these areas of electrical contact of the housing.

The upper areas of electrical contact of the electronic card 1 are placed facing the areas of electrical contact of the protective partition 3, in electrical contact with these areas of electrical contact of the protective partition.

Thus, the assembly of the housing 2 and the protective partition 3 is electrically connected to the electrical ground of the electronic card 1.

At least one area of contact of the housing 8 is placed facing at least one area of contact of the protective partition 3, and at least one area of electrical contact of the housing 2 is placed facing at least one area of electrical contact of the protective partition 3, on both sides of the electronic card 1.

The electronic module 100 comprises a series of securing elements 20, which are designed to render the electronic card 1, the housing 2 and the protective partition 3 integral.

The housing 2, the electronic card and the protective partition 3 are thus secured together by the securing elements 20.

FIG. 5 illustrates the assembly of an electronic module. The electronic module 100 comprises a cover 21 forming a vessel, which is designed to be placed on the housing 2 in order to close the housing.

FIG. 6 is a view in cross-section of an electronic module 100 once assembled, making it possible to visualise the placing of the electronic card 1 between the housing 2 and the protective partition 3.

All of the areas of contact of the housing 8 are flat and coplanar, and define a contact plane of the housing, parallel to the base of the housing 6, and raised in relation to the base of the housing by a height of more than 12 mm, more than the maximal thickness of the electronic components welded on the lower face of the electronic card 14, such that the electronic components welded on the lower face of the electronic card are not in contact with the housing 2, once the electronic card is placed in electrical contact with the housing.

The plane of contact of the protective partition 3 is parallel to the main plane of the protective partition, and is offset in relation to the main plane of the protective partition by a height H2 of more than 12 mm, in particular more than the maximal thickness of the electronic components welded on the upper face of the electronic card 15, such that these electronic components welded on the upper face of the electronic card are not in electrical contact with the protective partition, once the electronic card is placed in electrical contact with the protective partition.

In addition, the areas of contact of the housing 8 are electrical areas of contact of the housing, and are designed to guarantee an electrical contact between the housing 2 and an electrical ground of the electronic card 1.

Similarly, the areas of contact of the protective partition 16 are areas of electrical contact of the protective partition, and are designed to guarantee an electrical contact between the protective partition 3 and an electrical ground of the electronic card 1.

FIG. 7 represents a securing element 20 according to an embodiment of the invention. A securing element is a combination of characteristics of the electronic module which make it possible to render the housing 2, the electronic card 1 and the protective partition 3 integral.

The securing element 20 comprises:
a portion of an upper area of electrical contact 22 of the electronic card 1;
a portion of a lower area of electrical contact 23 of the electronic card 1,
   these two areas of contact being placed facing one another;
a portion of an area of electrical contact of the housing 24 placed facing the portion of a lower area of electrical contact of the electronic card;
a portion of an area of electrical contact of the protective partition 25 placed facing the portion of an upper area of electrical contact of the electronic card.

The securing element also comprises:
a bore in the electronic card 26;
a bore in the protective partition 27;
a bore in the housing 28,
these bores being coaxial; and
a screw which passes through all of the bores, not represented here, securing the protective partition, the housing, and the electronic card mechanically.

According to another embodiment, not represented, the securing element comprises:
a securing bore in the electronic card;
a bore respectively in the housing or the protective partition;
a securing stud formed respectively in the protective partition of the housing, and the securing stud being designed to be forced into the bores in order to secure the protective partition, the housing and the electronic card mechanically.

The securing element comprises an area of electrical contact, and also assures an electrical contact between the housing, the protective partition and an electrical ground of the electronic card.

1. Electronic module comprising:
An electronic card;
A housing in which the electronic card is placed;
A protective partition which is secured on the housing and the electronic card, such that the electronic card is engaged between the housing and the protective partition;
At least one securing element designed to render the electronic card, the housing and the protective partition integral,
wherein:
the housing and the protective partition are made of electrically conductive materials;
the housing, the electronic card and the protective partition are secured together by the at least one securing element;
at least one securing element comprises an electrical contact area, and also assures an electrical contact between the housing, the protective partition and an electrical ground of the electronic card.

2. Electronic module according to claim 1, wherein the housing and the protective partition form an electromagnetic protective enclosure, which is designed to protect the exterior environment against the electromagnetic fields produced by the electronic card, and protect the electronic card against the exterior environment, in particular against electromagnetic disturbances.

3. Electronic module according to claim 1, wherein a face of the electronic card, known as the lower face of the electronic card, is placed in contact with the housing, and a face of the electronic card known as the upper face of the electronic card is in electrical contact with the protective partition.

4. Electronic module according to claim 1, wherein the housing comprises a base, in particular a substantially flat base, and a peripheral border, which is substantially perpendicular to the base of the housing and surrounds the base of the housing.

5. Electronic module according to claim 1, wherein the housing comprises at least one area of contact, which is designed to be placed in contact with the electronic card during the assembly of the electronic module.

6. Electronic module according to claim 1, wherein the housing comprises at least one contact stud, i.e. at least one volume of the housing placed on the base of the housing.

7. Electronic module according to claim 5, wherein at least one area of contact of the housing is an area of electrical contact of the housing, and is designed to guarantee an electrical contact between the housing and an electrical ground of the electronic card.

8. Electronic module according to claim 4, wherein the base of the housing, the peripheral border of the housing and the contact studs are produced in a single piece, for example by moulding, or by machining.

9. Electronic module according to claim 3, wherein the electronic card comprises:
on the upper face, at least one upper area of contact of the electronic card;
on the lower face, at least one lower area of contact of the electronic card;
at least one upper area of contact of the electronic card being an upper electrical area of contact of the electronic card, and at least one lower area of contact of the card being a lower electrical area of contact of the electronic card.

10. Electronic module according to claim 1, wherein the protective partition contains a plurality of areas of contact, known as areas of contact of the protective partition, which are designed to be placed in contact with the electronic card during the assembly of the electronic module.

11. Electronic module according to claim 10, wherein at least one area of contact of the protective partition is an electrical area of contact of the protective partition, and is designed to guarantee an electrical contact between the protective partition and an electrical ground of the electronic card.

12. Electronic module according to claim 7, wherein a securing element comprises:
a portion of an upper area of electrical contact of the electronic card;
a portion of a lower area of electrical contact of the electronic card, these two areas of contact being placed facing one another;
a portion of an area of electrical contact of the housing placed facing the portion of a lower area of electrical contact of the electronic card;
a portion of an area of electrical contact of the protective partition placed facing the portion of an upper area of electrical contact of the electronic card.

13. Electronic module according to claim 2, wherein a face of the electronic card, known as the lower face of the electronic card, is placed in contact with the housing, and a face of the electronic card known as the upper face of the electronic card is in electrical contact with the protective partition.

14. Electronic module according to claim 2, wherein the housing comprises a base, in particular a substantially flat base, and a peripheral border, which is substantially perpendicular to the base of the housing and surrounds the base of the housing.

15. Electronic module according to claim 2, wherein the housing comprises at least one area of contact, which is designed to be placed in contact with the electronic card during the assembly of the electronic module.

16. Electronic module according to claim 2, wherein the housing comprises at least one contact stud, i.e. at least one volume of the housing placed on the base of the housing.

17. Electronic module according to claim 6, wherein the base of the housing, the peripheral border of the housing and the contact studs are produced in a single piece, for example by moulding, or by machining.

18. Electronic module according to claim 2, wherein the protective partition contains a plurality of areas of contact, known as areas of contact of the protective partition, which are designed to be placed in contact with the electronic card during the assembly of the electronic module.

19. Electronic module according to claim 9, wherein a securing element comprises:
a portion of an upper area of electrical contact of the electronic card;
a portion of a lower area of electrical contact of the electronic card,
these two areas of contact being placed facing one another;
a portion of an area of electrical contact of the housing placed facing the portion of a lower area of electrical contact of the electronic card;
a portion of an area of electrical contact of the protective partition placed facing the portion of an upper area of electrical contact of the electronic card.

20. Electronic module according to claim 3, wherein the housing comprises a base, in particular a substantially flat base, and a peripheral border, which is substantially perpendicular to the base of the housing and surrounds the base of the housing.
